(19) United States
(12) Patent Application Publication
(10) Pub. No.: US 2024/0313723 A1
(43) Pub. Date: Sep. 19, 2024

(54) SEMICONDUCTOR DEVICE

(71) Applicant: LAPIS Technology Co., Ltd., Yokohama (JP)

(72) Inventor: Tetsuo OOMORI, Yokohama (JP)

(73) Assignee: LAPIS Technology Co., Ltd., Yokohama (JP)

(21) Appl. No.: 18/604,433

(22) Filed: Mar. 13, 2024

(30) Foreign Application Priority Data
Mar. 15, 2023 (JP) 2023-040559

(51) Int. Cl. H03F 3/45; G05F 3/26

(52) U.S. Cl. CPC H03F 3/45273; G05F 3/267

(57) ABSTRACT

A semiconductor device includes: an output terminal outputting an output voltage; a bipolar transistor outputting a collector current to an output node; a bias current generation part including a first node, a first constant current source, and a first transistor connected in parallel with the first constant current source, and generating a bias current; a differential input part including a differential pair and a second node, in which the differential pair generates at the second node a control voltage according to a difference between the reference voltage and the voltage corresponding to the output voltage; and a drive part including a current supply circuit, a third node, and a second transistor controlling a potential of the third node according to the control voltage. The first transistor controls the bias current according to the control voltage.

### CROSS-REFERENCE TO RELATED APPLICATION

This application claims the priority benefits of Japanese application no. 2023-040559, filed on Mar. 15, 2023. The entirety of the above-mentioned patent application is hereby incorporated by reference herein and made a part of this specification.

### BACKGROUND

### Technical Field

The disclosure relates to a semiconductor device.

### Description of Related Art

A regulator circuit, which is a stabilized power supply circuit, is generally used as the power supply in systems equipped with microcomputers, AD/DA converters, motors, various communication systems, various sensors, etc. If these systems have high power consumption, the output current required for the regulator is also large, so a bipolar transistor that can easily output a large current may be used as the output element of the regulator.

For example, Patent Document 1 (Japanese Patent Application Laid-Open No. 2005-25595) discloses a semiconductor device which includes an NPN bipolar transistor that supplies an output current to a load connected to an output terminal, a differential amplifier composed of a MOS (metal oxide semiconductor) transistor, and a PchMOS (P-Channel metal oxide semiconductor) transistor that has a gate connected to the output of the differential amplifier and supplies a drain current to the NPN bipolar transistor to control the base current of the NPN bipolar transistor and control the output voltage.

However, for the regulator circuit whose output element is a bipolar transistor, like the semiconductor device described in Patent Document 1, it is difficult to handle a light load with low current consumption due to the characteristics of the bipolar transistor.

For example, in the semiconductor device described in Patent Document 1, the output voltage may rise when the load of the output element changes to a light load (or there is no load). Specifically, since the drain current of the PchMOS transistor is controlled by an active load composed of the MOS transistor of the differential amplifier, the drain current cannot be reduced to or below a certain value. A countermeasure is, for example, to adjust the minimum drain current amount of the PchMOS transistor to be suitable for the minimum base current value of the NPN bipolar transistor during a light load.

However, in the case where the above countermeasure is taken, if the variations in the amplification factor hFE of the NPN bipolar transistor are smaller than expected, the supply amount of the base current of the NPN bipolar transistor may be insufficient when a high load is connected, causing the output voltage to drop.

The semiconductor device described in Patent Document 1 also has a problem that the output voltage may further rise due to the leakage current of the PchMOS transistor when the environmental temperature or element temperature is high and especially when the load of the output element is a light load (or there is no load).

The disclosure provides a semiconductor device that is capable of accepting variations in the amplification factor of the bipolar transistor and supporting a wide load range while suppressing fluctuations in the output voltage even when the environmental temperature or element temperature is high.

### SUMMARY

A semiconductor device according to an embodiment of the disclosure includes: an output terminal that outputs an output voltage; a bipolar transistor that outputs a collector current according to an amount of a base current and supplies the collector current to an output node to which the output terminal is connected; a bias current generation part that includes a first node, a first constant current source connected to the first node, and a first transistor connected in parallel with the first constant current source with respect to the first node, and generates a bias current; a differential input part that includes a differential pair and a second node, in which a current corresponding to the bias current generated by the bias current generation part flows through the differential pair, and a reference voltage and a voltage corresponding to the output voltage are input to the differential pair, and the differential pair generates at the second node a control voltage according to a difference between the reference voltage and the voltage corresponding to the output voltage; and a drive part that includes a current supply circuit, a third node to which a base of the bipolar transistor is connected, and a second transistor controlling a potential of the third node according to the control voltage. The first transistor controls the bias current generated by the bias current generation part according to the control voltage of the differential input part.

### BRIEF DESCRIPTION OF THE DRAWINGS

FIG. 1 is a diagram showing the configuration of the semiconductor device of Example 1.

FIG. 2 is a circuit diagram of the semiconductor device of Example 1.

FIG. 3 is a circuit diagram of the semiconductor device of a comparative example.

FIG. 4 is a line regulation characteristic simulation diagram of the semiconductor device of the comparative example.

FIG. 5 is a line regulation characteristic simulation diagram of the semiconductor device of Example 1.

FIG. 6 is a diagram showing the configuration of the semiconductor device of Example 2.

FIG. 7 is a circuit diagram of the semiconductor device of Example 2.

### DESCRIPTION OF THE EMBODIMENTS

Examples of the disclosure will be described in detail below with reference to the drawings.

### Example 1

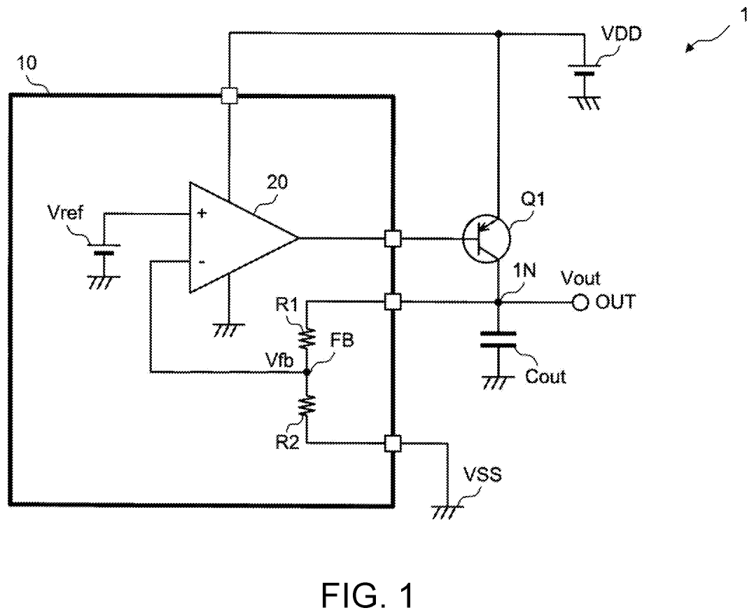

FIG. 1 is a diagram showing the configuration of a semiconductor device 1 of Example 1.

The semiconductor device 1 is a series regulator type stabilized power supply circuit that outputs a predetermined output voltage Vout corresponding to a reference voltage Vref according to a load (not shown) from an output terminal OUT.

The semiconductor device 1 includes a bipolar transistor Q1 and a controller 10 that is an IC (integrated circuit) for controlling the base current of the bipolar transistor Q1. That is, in this example, the semiconductor device 1 is a stabilized power supply circuit, which includes the controller 10 and the bipolar transistor Q1 externally connected to the controller 10.

The bipolar transistor Q1 is a PNP-type bipolar transistor, and has an emitter connected to a power supply voltage VDD and a collector connected to an output node IN. The bipolar transistor Q1 sends a current according to the amount of the base current from the collector to the output terminal OUT via the output node IN, and applies a voltage to the load (not shown).

A capacitor Cout is connected between the output node IN and a ground voltage VSS. The capacitor Cout is a capacitor for smoothing the output voltage Vout when the load connected to the output terminal OUT fluctuates.

The controller 10 is provided between the power supply voltage VDD and the ground voltage VSS, and is an IC device including an operational amplifier 20 and resistors R1 and R2.

The resistors R1 and R2 are connected in series with each other between the output terminal OUT and the ground voltage VSS. One end of the resistor R1 is connected to the output node IN, and the other end is connected to a node FB. Furthermore, one end of the resistor R2 is connected to the node FB, and the other end is connected to the ground voltage VSS. That is, a potential Vfb corresponding to the output terminal OUT (output node IN) is generated at the node FB between the resistors R1 and R2.

The operational amplifier 20 receives the power supply voltage VDD and the ground voltage VSS as operating voltages. The operational amplifier 20 has a non-inverting input terminal connected to a reference voltage Vref, and an inverting input terminal connected to the node FB. Further, the output terminal of the operational amplifier 20 is connected to the base of the bipolar transistor Q1.

The operational amplifier 20 controls the base current of the bipolar transistor Q1 so that the output voltage Vout has a voltage value corresponding to the reference voltage Vref.

That is, the bipolar transistor Q1 outputs a current from the collector by the base current controlled by the operational amplifier 20, so that the output voltage Vout having a predetermined voltage value corresponding to the reference voltage Vref is applied to the load (not shown) connected to the output terminal OUT.

Further, if the load fluctuates, the operational amplifier 20 changes the base current of the bipolar transistor Q1 to a current value corresponding to the difference between the reference voltage Vref and the potential Vfb of the node FB corresponding to the output voltage Vout. Thereby, the bipolar transistor Q1 outputs a current from the collector, so that the output voltage Vout having a predetermined voltage value corresponding to the reference voltage Vref is applied to the load in response to fluctuations of the load connected to the output terminal OUT.

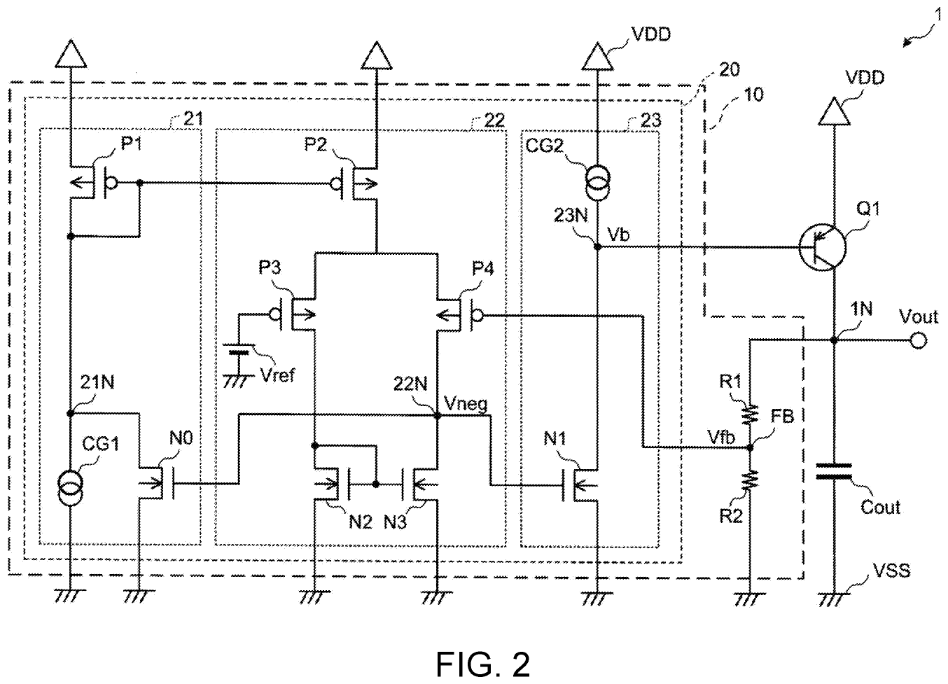

The semiconductor device 1 of this example will be described using FIG. 2.

FIG. 2 is a diagram showing a circuit diagram of the semiconductor device 1 according to Example 1.

The operational amplifier 20 includes a bias current generation part 21, a differential input part 22, and a drive part 23.

The bias current generation part 21 includes a node 21N, a p-type MOS transistor P1, a constant current source CG1, and an n-type MOS transistor NO.

The MOS transistor P1 has a source connected to the power supply voltage VDD, a drain connected to the node 21N, and a gate connected to the drain.

Further, the constant current source CG1 is connected between the node 21N and the ground voltage VSS, and generates a predetermined constant current by receiving supply of the potential of the node 21N.

Further, the MOS transistor NO has a drain connected to the node 21N and a source connected to the ground voltage VSS. That is, the constant current source CG1 and the MOS transistor NO are connected in parallel with each other between the node 21N and the ground voltage VSS.

The current flowing between the drain and source of the MOS transistor P1, which is the bias current of the bias current generation part 21, is the sum of the current value of the constant current source CG1 and the current value of the current flowing between the drain and source of the MOS transistor NO.

The differential input part 22 includes p-type MOS transistors P2, P3, and P4, n-type MOS transistors N2 and N3, and a node 22N.

The MOS transistor P2 has a source connected to the power supply voltage VDD and a gate connected to the gate of the MOS transistor P1 of the bias current generation part 21. That is, the MOS transistor P2 is connected in a current mirror manner to the MOS transistor P1 of the bias current generation part 21, and the drain current of the MOS transistor P1 of the bias current generation part 21 is copied. That is, the MOS transistor P2 of the differential input part 22 functions as the current source of the differential input part 22.

The MOS transistors P3 and N2 and the MOS transistors P4 and N3 are connected in parallel with each other between the drain of the MOS transistor P2 and the ground voltage VSS.

The MOS transistor P3 has a source connected to the drain of the MOS transistor P2 and a gate connected to the reference voltage Vref. Moreover, the MOS transistor P4 has a source connected to the drain of the MOS transistor P2, a gate connected to the node FB between the resistors R1 and R2, and a drain connected to the node 22N. That is, the MOS transistors P3 and P4 function as the differential pair of the differential input part 22.

The MOS transistor N2 has a drain connected to the drain of the MOS transistor P3, a source connected to the ground voltage VSS, and a gate connected to the drain. The MOS transistor N3 has a drain connected to the node 22N, a source connected to the ground voltage VSS, and a gate connected to the gate of the MOS transistor N2. That is, the MOS transistors N2 and N3 are connected in a current mirror manner and function as the load part of the differential input part 22.

Accordingly, a potential Vneg is generated at the node 22N of the differential input part 22, which is a control voltage according to the difference between the reference voltage Vref and the potential Vfb that is applied to the node FB between the resistors R1 and R2 and corresponds to the output terminal OUT (output node IN).

The sum of the current values flowing through the MOS transistors P3 and N2 and the MOS transistors P4 and N3 is equal to the drain current of the MOS transistor P2.

Further, the gate of the MOS transistor NO of the bias current generation part 21 is connected to the node 22N of the differential input part 22. That is, the MOS transistor NO of the bias current generation part 21 allows a current to flow between the drain and source according to the potential Vneg of the node 22N of the differential input part 22. In other words, the MOS transistor NO of the bias current generation part 21 controls the amount of the bias current (current between the source and drain of the MOS transistor P1) flowing through the bias current generation part 21 according to the potential Vneg of the node 22N of the differential input part 22.

The drive part 23 includes a constant current source CG2, a MOS transistor N1, and a node 23N. The constant current source CG2 is connected between the power supply voltage VDD and the node 23N, and receives supply of the power supply voltage VDD to generate a predetermined constant current. Further, the MOS transistor N1 has a drain connected to the node 23N, a source connected to the ground voltage VSS, and a gate connected to the node 22N of the differential input part 22. Further, the node 23N is connected to the base of the bipolar transistor Q1.

Thus, the MOS transistor N1 allows a current to flow between the drain and source according to the potential Vneg of the node 22N of the differential input part 22, and controls the potential Vb of the node 23N. That is, the MOS transistor N1 of the drive part 23 controls the potential Vb of the node 23N to control the amount of the sink current from the base of the bipolar transistor Q1.

The MOS transistor N1 is set with the minimum value of the drain current so as to correspond to the minimum potential of the potential Vb of the node 23N, which is the minimum base current (sink current) of the bipolar transistor Q1, when the load connected to the output terminal OUT is a light load.

As described above, the operational amplifier 20 controls the amount of the sink current from the base of the bipolar transistor Q1 so that the output voltage Vout having a predetermined voltage value corresponding to the reference voltage Vref is applied to the load according to fluctuations of the load connected to the output terminal OUT.

For example, when the load connected to the output terminal OUT of the semiconductor device 1 of Example 1 changes from a normal load state to a high load state, the output voltage Vout decreases. Therefore, the semiconductor device 1 operates to increase the collector current of the bipolar transistor Q1 to increase the output voltage Vout.

Specifically, when the load is switched to a high load, the potential Vfb of the node FB between the resistors R1 and R2 decreases in accordance with the decrease of the output voltage Vout. As the potential Vfb of the node FB decreases, the amount of the source-drain current of the MOS transistor P4 of the differential input part 22 increases. Therefore, the potential Vneg of the node 22N of the differential input part 22 increases.

As the potential Vneg of the node 22N of the differential input part 22 increases, the amount of the current flowing between the drain and source of the MOS transistor N1 of the drive part 23 increases, and the potential Vb of the node 23N of the drive part 23 decreases.

As the potential Vb of the node 23N of the drive part 23 decreases, the potential difference between the emitter and base of the bipolar transistor Q1 increases, the amount of the sink current from the base of the bipolar transistor Q1 increases, and the collector current increases.

Furthermore, as described above, in the semiconductor device 1 of Example 1, the MOS transistor N0 is provided in the bias current generation part 21, and the gate of the MOS transistor N0 is connected to the node 22N of the differential input part 22.

Therefore, the amount of the current flowing between the drain and source of the MOS transistor N0 increases as the potential Vneg of the node 22N of the differential input part 22 increases. That is, the amount of the current flowing between the source and drain of the MOS transistor P1 of the bias current generation part 21 increases. In other words, when the load connected to the output terminal OUT changes to a high load, the differential input part 22 increases the current flowing through the MOS transistor N0 of the bias current generation part 21 to increase the amount of the current flowing between the source and drain of the MOS transistor P1, which is the bias current of the bias current generation part 21.

As a result, the amount of the current flowing between the source and drain of the MOS transistor P2 of the differential input part 22, that is, the total amount of the current flowing through the differential input part 22, increases and the potential Vneg of the node 22N of the differential input part 22 further increases.

Thus, the amount of the current flowing between the drain and source of the MOS transistor N1 of the drive part 23 can be further increased to further reduce the potential Vb of the node 23N. That is, the amount of the sink current from the base of the bipolar transistor Q1 can be further increased to further increase the collector current.

Therefore, according to the semiconductor device 1 of Example 1, the amount of the current flowing through the bias current generation part 21 is controlled by the MOS transistor N0 of the bias current generation part 21 even when the load changes to a high load. Thus, it is possible to generate the output voltage Vout in a desired voltage range even in a large current region of the collector current where the amplification factor hFE of the bipolar transistor Q1 fluctuates. That is to say, when the load on the output terminal OUT changes to a high load, the semiconductor device 1 is capable of suppressing a decrease in the output voltage Vout applied to the high load.

On the other hand, for example, when the load connected to the output terminal OUT of the semiconductor device 1 of Example 1 changes from a normal load state to a light load state (or no load state), the output voltage Vout increases. Therefore, the semiconductor device 1 operates to reduce the collector current of the bipolar transistor Q1 to lower the output voltage Vout.

Specifically, when the load changes to a light load, the potential Vfb of the node FB between the resistors R1 and R2 increases in accordance with the increase of the output voltage Vout. As the potential Vfb of the node FB increases, the amount of the source-drain current of the MOS transistor P4 of the differential input part 22 decreases. Therefore, the potential Vneg of the node 22N of the differential input part 22 decreases.

As the potential Vneg of the node 22N of the differential input part 22 decreases, the amount of the current flowing between the drain and source of the MOS transistor N1 of the drive part 23 decreases, and the potential Vb of the node 23N of the drive part 23 increases.

As the potential Vb of the node 23N of the drive part 23 increases, the potential difference between the emitter and base of the bipolar transistor Q1 decreases, the amount of the sink current from the base of the bipolar transistor Q1 decreases, and the collector current decreases.

Furthermore, as the potential Vneg of the node 22N of the differential input part 22 decreases, the amount of the current flowing between the drain and source of the MOS transistor N0 decreases. That is, the amount of the current flowing between the source and drain of the MOS transistor P1 of the bias current generation part 21 decreases. In other words, when the load connected to the output terminal OUT changes to a light load, the differential input part 22 reduces the current flowing through the MOS transistor N0 of the bias current generation part 21 to reduce the amount of the current flowing between the source and drain of the MOS transistor P1, which is the bias current of the bias current generation part 21.

As a result, the amount of the current flowing between the source and drain of the MOS transistor P2 of the differential input part 22, that is, the total amount of the current flowing through the differential input part 22, decreases and the potential Vneg of the node 22N of the differential input part 22 further decreases.

Thus, the amount of the current flowing between the drain and source of the MOS transistor N1 of the drive part 23 can be further reduced to further increase the potential Vb of the node 23N. Thereby, the amount of the sink current from the base of the bipolar transistor Q1 can be further reduced to further reduce the collector current. That is to say, when the load connected to the output terminal OUT changes to a light load, the semiconductor device 1 is capable of suppressing an increase in the output voltage Vout applied to the light load.

Therefore, according to the semiconductor device 1 of Example 1, it is possible to generate the output voltage Vout in a desired voltage range by controlling the amount of the current flowing through the bias current generation part 21 using the MOS transistor N0 of the bias current generation part 21, even when a light load state (or no load state) is connected.

Furthermore, according to the semiconductor device 1 of Example 1, it is possible to suppress an increase in the output voltage Vout even when a light load state (or no load state) is connected and the environmental temperature or element temperature is high.

For example, even if a leakage current occurs between the drain and source of the MOS transistor N1 in a high temperature environment, the semiconductor device 1 reduces the amount of the current flowing through the bias current generation part 21 in accordance with the increase of the output voltage Vout corresponding to the occurrence of the leakage current, thereby lowering the potential Vneg of the node 22N of the differential input part 22 to cancel out the leakage current generated in the MOS transistor N1 of the drive part 23. Accordingly, the semiconductor device 1 is capable of generating the output voltage Vout in a desired voltage range even when the load changes to a light load in a high temperature environment.

The output voltage characteristics of Example 1 will be described below using a comparative example.

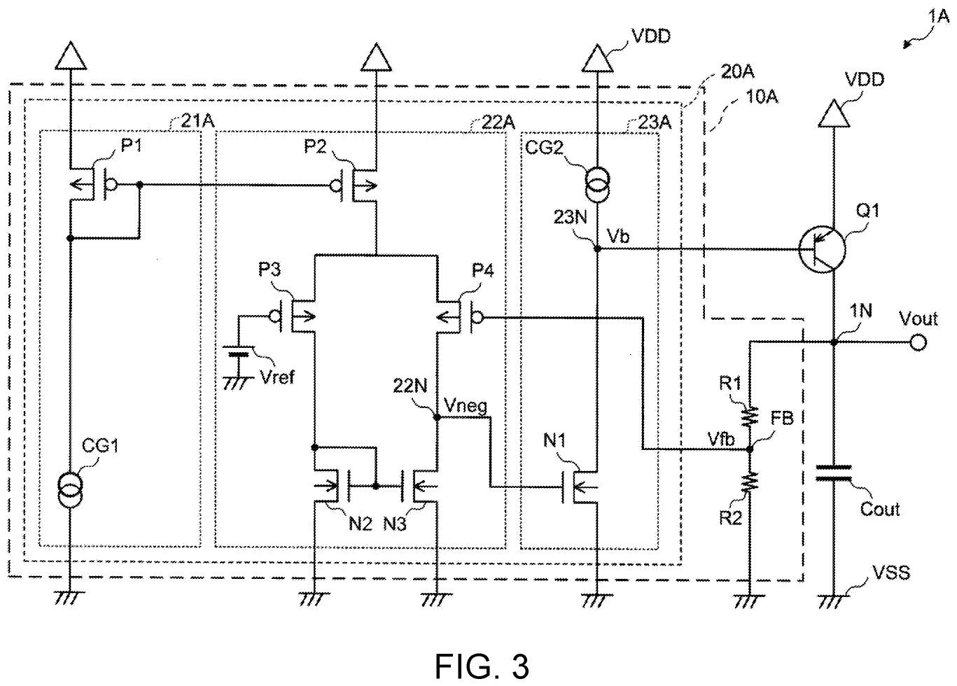

FIG. 3 is a circuit diagram of a semiconductor device 1A according to a comparative example.

As shown in FIG. 3, in the semiconductor device 1A of the comparative example, the circuit configurations of the differential input part 22A and the drive part 23A are the same as the circuit configurations of the differential input part 22 and the drive part 23 in the semiconductor device 1 of Example 1. The semiconductor device 1A of the comparative example is different from Example 1 in that the bias current generation part 21A is not provided with the MOS transistor N1. That is, in the semiconductor device 1A of the comparative example, a constant current constantly flows through the bias current generation part 21A.

In the semiconductor device 1 of Example 1 and the semiconductor device 1A of the comparative example, transistor characteristics are respectively set so that, when the load of the output terminal OUT changes to a light load in a normal temperature environment, the output voltage Vout having a target voltage value is applied from the output terminal OUT to the light load.

Specifically, it is assumed that the bipolar transistor Q1 has a large variation in the predetermined amplification factor hFE, and the minimum drain current of the MOS transistor N1 of the drive part 23A is set to be suitable for the amount of the base current during a light load, which is the minimum value of the base current of the bipolar transistor Q1.

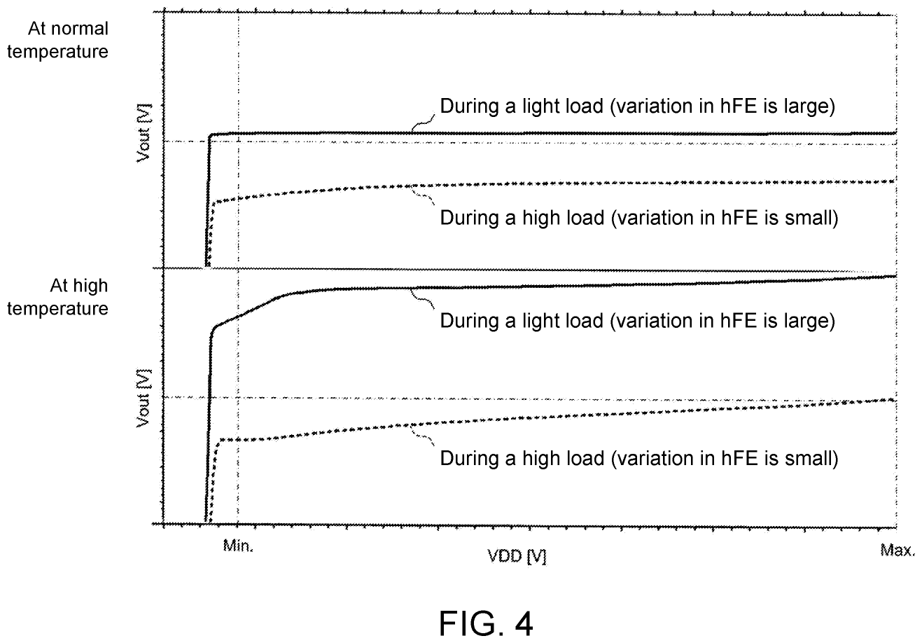

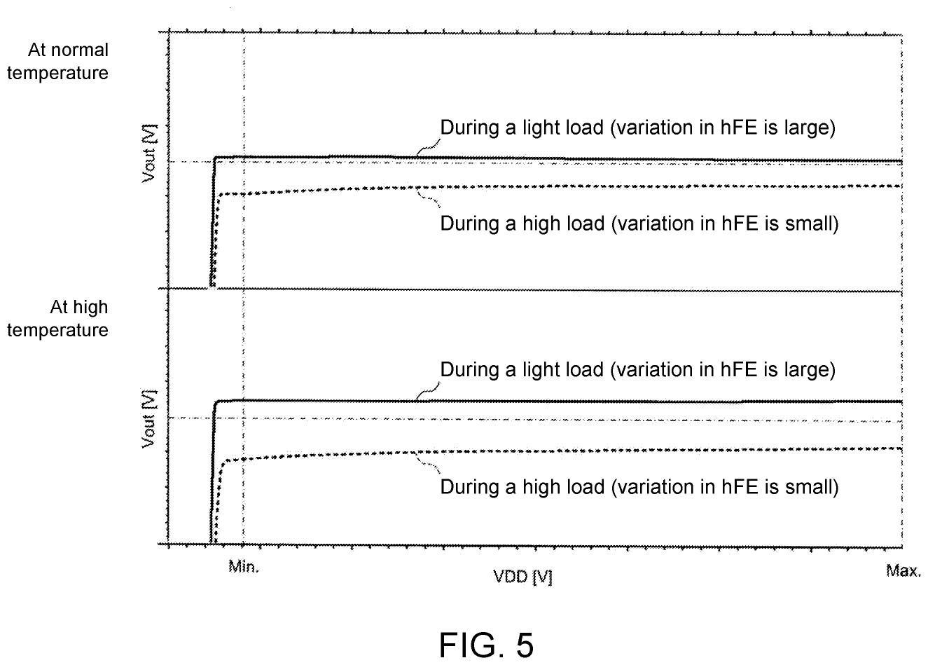

FIG. 4 is a line regulation characteristic simulation diagram of the semiconductor device 1A according to the comparative example. Moreover, FIG. 5 is a line regulation characteristic simulation diagram of the semiconductor device 1 according to Example 1.

In FIG. 4 and FIG. 5, the upper graph shows the line regulation characteristics at the normal temperature, and the lower graph shows the line regulation characteristics in a high temperature environment.

In each graph, the vertical axis indicates the output voltage Vout, and the one-dot chain line perpendicular to the vertical axis indicates the target voltage value of the output voltage Vout. Moreover, the horizontal axis indicates the power supply voltage VDD, and the power supply voltage VDD fluctuates in the range of two one-dot chain lines Min. and Max perpendicular to the horizontal axis.

Further, in each graph, the solid line indicates the behavior of the output voltage Vout when the load of the output terminal OUT is a light load, and the broken line indicates the behavior of the output voltage Vout when the load of the output terminal OUT is a high load.

In FIG. 4 and FIG. 5, a light load refers to a load that supplies a current of several uA from the output terminal OUT, and a high load refers to a load that supplies a current of several 100 mA from the output terminal OUT. The light load and high load here are merely examples and are not intended to limit the operating range of Example 1.

In addition, FIG. 4 and FIG. 5 are described considering variations in the amplification factor hFE of the bipolar transistor Q1, and assuming that there is a large variation in the amplification factor hFE of the bipolar transistor Q1 during a light load and there is a small variation in the amplification factor hFE of the bipolar transistor Q1 during a high load.

As shown in FIG. 4, in the semiconductor device 1A of the comparative example, the above settings provide an output characteristic that is close to the target voltage value of the output voltage Vout when the load is a light load in the normal temperature environment.

However, when the load is a high load in the normal temperature environment and the variation in the amplification factor hFE of the bipolar transistor Q1 is small, the output voltage Vout decreases. This is because the variation in the amplification factor hFE becomes small and the required amount of the base current (sink current) of the bipolar transistor Q1 becomes large, so when the load becomes a high load, the base current (sink current) becomes insufficient, the collector current flowing through the high load decreases, and the output voltage Vout decreases.

Further, as shown in FIG. 4, in the semiconductor device 1A of the comparative example, when the load is a light load in a high temperature environment, the output voltage Vout increases. This is because a leakage current occurs between the drain and source of the MOS transistor N1 of the drive part 23 in a high temperature environment, and the potential Vb of the node 23N decreases, which causes the base current (sink current) of the bipolar transistor Q1 to become larger than the amount required for a light load, and the amount of the collector current flowing through the light load increases and the output voltage Vout increases.

As shown in FIG. 5, in the semiconductor device 1 of Example 1, a decrease in the output voltage Vout is suppressed even when the load is a high load in the normal temperature environment and the variation in the amplification factor hFE of the bipolar transistor Q1 is small. This is because when the variation in the amplification factor hFE of the bipolar transistor Q1 is small and the required amount of the base current (sink current) of the bipolar transistor Q1 increases, the amount of the current flowing through the bias current generation part 21 increases in accordance with the decrease in the output voltage Vout.

Specifically, as described above, the amount of the current between the drain and source of the MOS transistor N1 of the bias current generation part 21 increases in accordance with the decrease in the voltage value of the output voltage Vout and the potential Vfb of the node FB, and the amount of the current flowing through the bias current generation part 21 increases. As the total current amount of the differential input part 22 is increased by the MOS transistor N1 of the bias current generation part 21, the potential Vneg of the node 22N of the differential input part 22 increases. Thus, the current flowing between the drain and source of the MOS transistor N1 of the drive part 23 increases to increase and compensate for the insufficient base current (sink current) of the bipolar transistor Q1.

Furthermore, as shown in FIG. 5, in the semiconductor device 1 of Example 1, an increase in the output voltage Vout is suppressed when the load is a light load in a high temperature environment. This is possible when a leakage current occurs between the drain and source of the MOS transistor N1 of the drive part 23 in a high temperature environment and the base current (sink current) of the bipolar transistor Q1 becomes larger than the amount required for a light load, the amount of the current flowing through the bias current generation part 21 decreases in accordance with the increase of the output voltage Vout.

Specifically, as described above, the amount of the current between the drain and source of the MOS transistor N1 of the bias current generation part 21 decreases in accordance with the increase in the voltage value of the output voltage Vout and the potential Vfb of the node FB, and the amount of the current flowing through the bias current generation part 21 decreases. As the total current amount of the differential input part 22 is reduced by the MOS transistor N1 of the bias current generation part 21, the potential Vneg of the node 22N of the differential input part 22 decreases. Thus, the current flowing between the drain and source of the MOS transistor N1 of the drive part 23 decreases to reduce and compensate for the base current (sink current) of the bipolar transistor Q1, which has increased by the leakage current of the MOS transistor N1.

In this way, the semiconductor device 1 of Example 1 is capable of suppressing fluctuations in the output voltage Vout in response to fluctuations in a wide load range even when the environmental temperature or element temperature is high and when the variations in the amplification factor hFE of the bipolar transistor Q1 change.

### Example 2

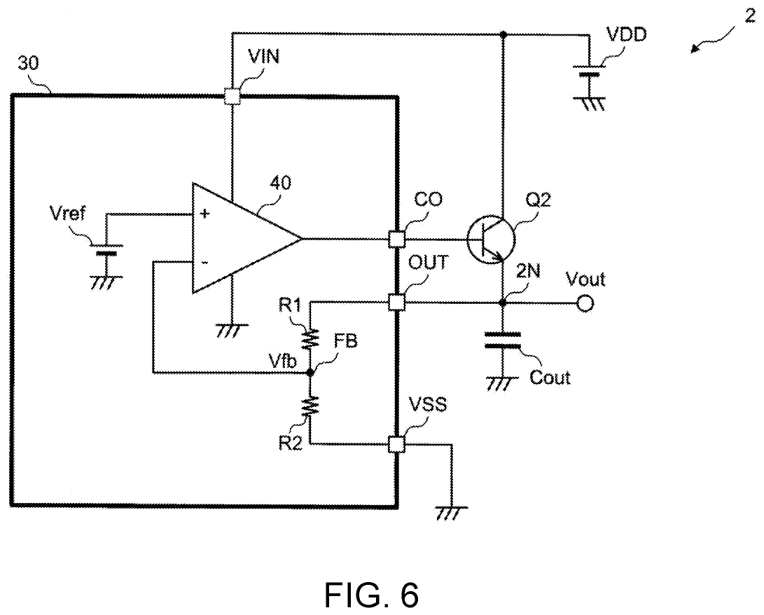

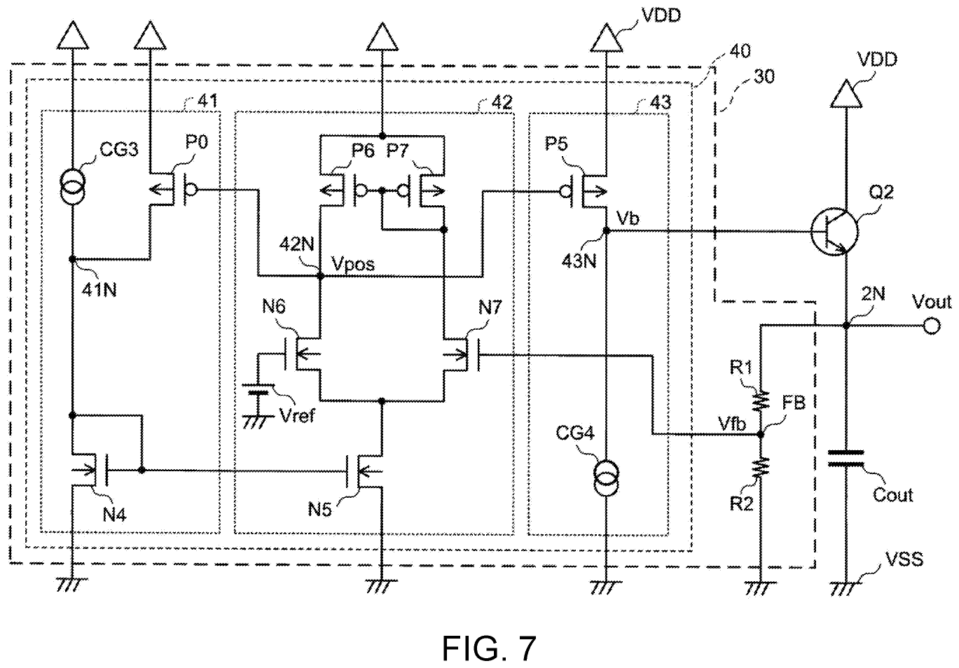

FIG. 6 is a diagram showing the configuration of a semiconductor device 2 according to Example 2. Further, FIG. 7 is a diagram showing a circuit diagram of the semiconductor device 2 according to Example 2.

The semiconductor device 2 of Example 2 is different from Example 1 in that the semiconductor device 2 includes an NPN-type bipolar transistor Q2 instead of the PNP-type bipolar transistor Q1 in the semiconductor device 1 of Example 1.

Further, a controller 30 in the semiconductor device 2 of Example 2 uses the NPN-type bipolar transistor Q2, and therefore the internal configuration of an operational amplifier 40 included in the controller 30 is different.

As shown in FIG. 6, the bipolar transistor Q2 is an NPN-type bipolar transistor, and has a collector connected to the power supply voltage VDD and an emitter connected to the output terminal OUT. The bipolar transistor Q2 sends a current from the emitter to the output terminal OUT and applies a voltage to a load (not shown).

As shown in FIG. 7, the operational amplifier 40 includes a bias current generation part 41, a differential input part 42, and a drive part 43.

The bias current generation part 41 includes an n-type MOS transistor N4, a constant current source CG3, and a p-type MOS transistor P0.

The MOS transistor N4 has a source connected to the ground voltage VSS, a drain connected to the node 41N, and a gate connected to the drain.

The constant current source CG3 is connected between the power supply voltage VDD and the node 41N, and receives supply of the power supply voltage VDD to generate a predetermined constant current.

The MOS transistor P0 has a drain connected to the node 41N and a source connected to the power supply voltage VDD. That is, the constant current source CG3 and the MOS transistor P0 are connected in parallel with each other between the node 41N and the power supply voltage VDD.

The current flowing between the drain and source of the MOS transistor N4, which is the bias current of the bias current generation part 41, is the sum of the current value of the constant current source CG3 and the current value flowing between the source and drain of the MOS transistor P0.

The differential input part 42 includes n-type MOS transistors N5, N6, and N7 and p-type MOS transistors P6 and P7.

The MOS transistor N5 has a source connected to the ground voltage VSS, and a gate connected to the gate of the MOS transistor N4 of the bias current generation part 41. That is, the MOS transistor N5 is connected in a current mirror manner to the MOS transistor N4 of the bias current generation part 41, and the drain current of the MOS transistor N4 of the bias current generation part 41 is copied. That is, the MOS transistor N5 of the differential input part 42 functions as the current source of the differential input part 42.

The MOS transistors N6 and P6 and the MOS transistors N7 and P7 are connected in parallel with each other between the drain of the MOS transistor N5 and the power supply voltage VDD.

The MOS transistor N6 has a source connected to the drain of the MOS transistor N5, a gate connected to the reference voltage Vref, and a drain connected to the node 42N. Further, the MOS transistor N7 has a source connected to the drain of the MOS transistor N5, and a gate connected to the node FB between the resistors R1 and R2. That is, the MOS transistors N6 and N7 function as the differential pair of the differential input part 22.

The MOS transistor P6 has a drain connected to the node 42N and a source connected to the power supply voltage VDD. The MOS transistor P7 has a drain connected to the drain of the MOS transistor N7, a source connected to the power supply voltage VDD, and a gate connected to the drain thereof and the gate of the MOS transistor P6. That is, the MOS transistors P6 and P7 are connected in a current mirror manner and function as the load part of the differential input part 42. The sum of the current values flowing through the MOS transistors P6 and N6 and the MOS transistors P7 and N7 is equal to the drain current of the MOS transistor N5.

Further, the gate of the MOS transistor P0 of the bias current generation part 41 is connected to the node 42N of the differential input part 42. That is, the MOS transistor P0 of the bias current generation part 41 allows a current to flow between the source and drain according to the potential Vpos of the node 42N of the differential input part 42.

The drive part 43 includes a p-type MOS transistor P5 and a constant current source CG4.

The MOS transistor P5 has a drain connected to the node 43N, a source connected to the power supply voltage VDD, and a gate connected to the node 42N of the differential input part 42. Further, the node 43N is connected to the base of the bipolar transistor Q1. Furthermore, the constant current source CG4 is connected between the node 43N and the ground voltage VSS, and receives supply of the potential Vb of the node 43N to generate a predetermined constant current.

Thus, the MOS transistor P5 allows a current to flow between the source and drain according to the potential Vpos of the node 42N of the differential input part 42, and changes the potential Vb of the node 43N to control the amount of the base current supplied to the base of the bipolar transistor Q1.

The semiconductor device 2 of Example 2 performs the same operation as the semiconductor device 1 of Example 1, and applies a predetermined output voltage Vout to the load connected to the output terminal OUT by controlling the amount of the base current supplied to the base of the bipolar transistor Q2.

For example, when the load connected to the output terminal OUT of the semiconductor device 2 of Example 2 changes from a normal load state to a high load state, the output voltage Vout decreases. Therefore, the semiconductor device 2 operates to increase the collector current of the bipolar transistor Q2 to increase the output voltage Vout.

Specifically, when the load changes to a high load, the potential Vfb of the node FB between the resistors R1 and R2 decreases in accordance with the decrease of the output voltage Vout. As the potential Vfb of the node FB decreases, the amount of the current flowing between the drain and source of the MOS transistor N7 of the differential input part 42 decreases. Accordingly, the amount of the current flowing between the drain and source of the MOS transistor N6 increases. Therefore, the potential Vpos of the node 42N of the differential input part 42 decreases.

As the potential Vpos of the node 42N of the differential input part 42 decreases, the amount of the current flowing between the source and drain of the MOS transistor P5 of the drive part 43 increases, and the potential Vb of the node 43N of the drive part 43 increases.

As the potential Vb of the node 43N of the drive part 43 increases, the voltage V_{BE} between the base and emitter of the bipolar transistor Q2 increases, the amount of the base current supplied to the base of the bipolar transistor Q2 increases, and the collector current increases.

Furthermore, as described above, in the semiconductor device 2 of Example 2, the MOS transistor P0 is provided in the bias current generation part 41, and the gate of the MOS transistor P0 is connected to the node 42N of the differential input part 42.

Therefore, as the potential Vpos of the node 42N of the differential input part 42 increases, the amount of the current flowing between the source and drain of the MOS transistor P0 increases. That is, the amount of the current flowing between the drain and source of the MOS transistor N4 of the bias current generation part 41 increases. In other words, when the load connected to the output terminal OUT changes to a high load, the differential input part 42 increases the current flowing through the MOS transistor P0 of the bias current generation part 41 to increase the amount of the current flowing between the source and drain of the MOS transistor N4, which is the bias current of the bias current generation part 41.

As a result, the amount of the current flowing between the drain and source of the MOS transistor N5 of the differential input part 42, that is, the total amount of the current flowing through the differential input part 42, increases. In addition, as the amount of the current flowing between the drain and source of the MOS transistor N5 further increases, the potential Vneg of the node 22N of the differential input part 42 further decreases.

Thus, the amount of the current flowing between the source and drain of the MOS transistor P5 of the drive part 43 can be further increased to further increase the potential Vb of the node 43N. Thereby, the amount of the base current supplied to the base of the bipolar transistor Q2 can be further increased to further increase the collector current. That is to say, when the load on the output terminal OUT changes to a high load, the semiconductor device 2 is capable of suppressing a decrease in the output voltage Vout applied to the high load.

Furthermore, as described above, assuming that the predetermined amplification factor hFE of the bipolar transistor Q2 has a large variation, the actual variation in the amplification factor hFE of the bipolar transistor Q2 may be small even though the minimum value (lower limit value) of the base current is set. In such a case, the semiconductor device 2 increases the amount of the current applied to the bias current generation part 41 by the MOS transistor P0 to compensate for the deficiency of the base current required for the large current supplied from the bipolar transistor Q2 to the high load, and thereby increases the total amount of the current flowing through the differential input part 42.

Thus, according to the semiconductor device 1 of Example 1, it is possible to generate the output voltage Vout in a desired voltage range by controlling the amount of the current flowing through the bias current generation part 41 using the MOS transistor P0 of the bias current generation part 41 even when the load changes to a high load.

On the other hand, for example, when the load connected to the output terminal OUT of the semiconductor device 2 of Example 2 changes from a normal load state to a light load state (or no load state), the output voltage Vout increases. Therefore, the semiconductor device 2 operates to reduce the collector current of the bipolar transistor Q2 to lower the output voltage Vout.

Specifically, when the load changes to a light load, the potential Vfb of the node FB between the resistors R1 and R2 increases in accordance with the increase of the output voltage Vout. As the potential Vfb of the node FB increases, the amount of the current flowing between the drain and source of the MOS transistor N7 of the differential input part 42 increases. Accordingly, the amount of the current flowing between the drain and source of the MOS transistor N6 decreases. Therefore, the potential Vpos of the node 42N of the differential input part 42 increases.

As the potential Vpos of the node 42N of the differential input part 42 increases, the amount of the current flowing between the source and drain of the MOS transistor P5 of the drive part 23 decreases, and the potential Vb of the node 23N of the drive part 23 decreases.

As the potential Vb of the node 23N of the drive part 23 decreases, the voltage V_{BE} between the base and emitter of the bipolar transistor Q2 decreases, the amount of the base current supplied to the base of the bipolar transistor Q2 decreases, and the collector current decreases.

Furthermore, as the potential Vpos of the node 42N of the differential input part 42 increases, the amount of the current flowing between the source and drain of the MOS transistor P0 decreases. That is, the amount of the current flowing between the drain and source of the MOS transistor N4 of the bias current generation part 41 decreases. In other words, when the load connected to the output terminal OUT changes to a light load, the differential input part 42 reduces the current flowing through the MOS transistor P0 of the bias current generation part 41 to reduce the amount of the current flowing between the source and drain of the MOS transistor N4, which is the bias current of the bias current generation part 41.

As a result, the amount of the current flowing between the drain and source of the MOS transistor N3 of the differential input part 42, that is, the total amount of the current flowing through the differential input part 42, decreases, and the potential Vpos of the node 42N of the differential input part 42 further decreases.

Thus, the amount of the current flowing between the source and drain of the MOS transistor P5 of the drive part 43 can be further reduced to further lower the potential Vb of the node 43N. That is, the amount of the base current supplied to the base of the bipolar transistor Q2 can be further reduced to further reduce the collector current. That is, when the load of the output terminal OUT changes to a light load, the semiconductor device 2 is capable of suppressing an increase in the output voltage Vout applied to the light load.

Thus, according to the semiconductor device 2 of Example 2, it is possible to generate the output voltage Vout in a desired voltage range by controlling the amount of the current flowing through the bias current generation part 41 using the MOS transistor P0 of the bias current generation part 41 even when the load changes to a light load state (or no load state).

Furthermore, for example, according to the semiconductor device 2 of Example 2, it is possible to suppress an increase in the output voltage Vout even when the load changes to a light load state (or no load state) and the environmental temperature or element temperature is high.

Specifically, even if a leakage current occurs between the source and drain of the MOS transistor P5 in a high temperature environment, the semiconductor device 2 reduces the amount of the current flowing through the bias current generation part 41 in accordance with the increase of the output voltage Vout corresponding to the occurrence of the leakage current, thereby increasing the potential Vpos of the node 42N of the differential input part 42 to cancel out the leakage current generated in the MOS transistor P5 of the drive part 43. Accordingly, the semiconductor device 2 is capable of generating the output voltage Vout in a desired voltage range even when the load changes to a light load in a high temperature environment.

In this way, the semiconductor device 2 of Example 2 is capable of suppressing fluctuations in the output voltage Vout in response to fluctuations in a wide load range even when the environmental temperature or element temperature is high and when there are variations in the amplification factor hFE of the bipolar transistor Q2.

In Examples 1 and 2, the operational amplifiers 20 and 40 are circuits including n-type and p-type MOS transistors. Thus, the controllers 10 and 30 may be manufactured by a CMOS process. Using the operational amplifiers 20 and 40 manufactured by a CMOS process may reduce the current consumption of the controllers 10 and 30 that control the bipolar transistors Q1 and Q2.

In addition, in Examples 1 and 2, the bipolar transistors Q1 and Q2 and the controller 10 may be mounted on the same IC device if the allowable loss in the packages of the semiconductor devices 1 and 2 is within an allowable range. In that case, it can be used as an IC device manufactured by a Bi-CMOS (Bipolar Complementary Metal Oxide Semiconductor) process and including the controllers 10 and 30 and the bipolar transistors Q1 and Q2.

Further, each element of the semiconductor devices 1 and 2 may be configured with a discrete IC.

Furthermore, in Examples 1 and 2, the operational amplifiers 20 and 40 may be replaced with an OTA (operational trans-conductance amplifier) circuit or a folded cascode circuit. In short, the configuration may be implemented if the differential input part includes a MOS transistor connected in a current mirror manner to the bias current generation part and the bias current generation part includes a MOS transistor that controls the current amount of the bias current generation part according to the output voltage Vout of the differential input part.

Specifically, in Example 1, the amount of the bias current can be increased or decreased by the MOS transistor N0 of the bias current generation part 21, and the current of the MOS transistor N1 of the drive part 23 (that is, the potential Vb of the node 23N, and the voltage V_{BE} between the base and emitter of the bipolar transistor Q1) is adjusted by the increase or decrease in the current of the MOS transistor P2 of the differential input part 22. Further, in Example 2, the amount of the bias current can be increased or decreased by the MOS transistor P0 of the bias current generation part 41, and the current of the MOS transistor P5 of the drive part 23 (that is, the potential Vb of the node 43N, and the voltage V_{BE} between the base and emitter of the bipolar transistor Q2) is adjusted by the increase or decrease in the current of the MOS transistor N5 of the differential input part 42.

Any configuration may be used if the differential circuit is capable of the above operation.

Furthermore, Example 1 illustrates a case where the drive part 23 includes the constant current source CG2 and the MOS transistor N1. However, in the drive part 23, a resistor may be used in place of the constant current source CG2 if the circuit configuration is capable of pulling up the potential Vb of the node 23N.

Similarly, in Example 2, a resistor may be used in place of the constant current source CG4 if the circuit configuration is capable of pulling down the potential Vb of the node 43N of the drive part 43.

Furthermore, although Example 1 illustrates a case where the MOS transistor N0 of the bias current generation part 21 is connected between the node 21N and the ground voltage VSS, a constant current source may be provided between the source of the MOS transistor N0 and the ground voltage VSS.

In the bias current generation part 21, the upper limit value of the amount of the current flowing between the drain and source of the MOS transistor N0 may be determined by providing a constant current source between the source of the MOS transistor N0 and the ground voltage VSS.

For example, when the upper limit value of the amount of the current flowing between the drain and source of the MOS transistor N0 is smaller than the upper limit value that can be adjusted by the size ratio of the MOS transistor N0, a current amount exceeding the intended range may flow between the drain and source of the MOS transistor N0. In this case, the phase margin of the operational amplifier 20 decreases, and the oscillation or output current is so large that it may exceed the package allowable loss and cause a fire.

Thus, the above problem may be prevented by providing a constant current source between the source of the MOS transistor N0 and the ground voltage VSS.

A resistor may be used to limit the current of the MOS transistor N0, in place of the constant current source provided between the source of the MOS transistor N0 and the ground voltage VSS.

Similarly, in Example 2, a constant current source or a resistor may be provided between the source of the MOS transistor P0 and the power supply voltage VDD.

What is claimed is:

1. A semiconductor device, comprising:
an output terminal that outputs an output voltage;
a bipolar transistor that outputs a collector current according to an amount of a base current and supplies the collector current to an output node to which the output terminal is connected;
a bias current generation part that comprises a first node, a first constant current source connected to the first node, and a first transistor connected in parallel with the first constant current source with respect to the first node, and generates a bias current;
a differential input part that comprises a differential pair and a second node, wherein a current corresponding to the bias current generated by the bias current generation part flows through the differential pair, and a reference voltage and a voltage corresponding to the output voltage are input to the differential pair, and the differential pair generates at the second node a control voltage according to a difference between the reference voltage and the voltage corresponding to the output voltage; and
a drive part that comprises a current supply circuit, a third node to which a base of the bipolar transistor is connected, and a second transistor controlling a potential of the third node according to the control voltage,
wherein the first transistor controls the bias current generated by the bias current generation part according to the control voltage of the differential input part.

2. The semiconductor device according to claim 1, wherein the bias current generation part comprises a third transistor connected in series to the first constant current source and the first transistor, and the differential input part comprises a fourth transistor connected in a current mirror manner to the third transistor.

3. The semiconductor device according to claim 1, wherein the bipolar transistor is a PNP-type bipolar transistor, and
each of the first transistor and the second transistor is an n-type MOS transistor.

4. The semiconductor device according to claim 3, wherein in the bias current generation part,
the first transistor has a drain connected to the first node, a source connected to a ground voltage, and a gate connected to the second node of the differential input part, and
the first constant current source is connected between the first node and the ground voltage.

5. The semiconductor device according to claim 4, wherein the bias current generation part comprises a second constant current source or a resistor between the source of the first transistor and the ground voltage.

6. The semiconductor device according to claim 1, wherein the bipolar transistor is an NPN-type bipolar transistor, and
each of the first transistor and the second transistor is a p-type MOS transistor.

7. The semiconductor device according to claim 6, wherein in the bias current generation part,
the first transistor has a source connected to a power supply voltage, a drain connected to the first node, and a gate connected to the second node of the differential input part, and
the first constant current source is connected between the power supply voltage and the first node.

8. The semiconductor device according to claim 7, wherein the bias current generation part comprises a second constant current source or a resistor between the power supply voltage and the source of the first transistor.

9. The semiconductor device according to claim 1, wherein the current supply circuit of the drive part is a constant current source or a resistor.

10. The semiconductor device according to claim 1, wherein the differential input part decreases a current flowing through the first transistor to decrease the bias current of the bias current generation part in response to a load connected to the output terminal changing to a light load, and
increases the current flowing through the first transistor to increase the bias current of the bias current generation part in response to the load connected to the output terminal changing to a high load.
